(19) United States
(12) Patent Application Publication
(10) Pub. No.: US 2008/0227294 A1
(43) Pub. Date: Sep. 18, 2008

(54) Method of making an interconnect structure

(76) Inventor: Daewoong Suh, Phoenix, AZ (US)

Correspondence Address: INTEL CORPORATION;c/o INTELLEVATE, LLC, P.O. BOX 52050, MINNEAPOLIS, MN, 55402, US

(21) Appl. No.: 11/717,291

(22) Filed: Mar. 12, 2007

(51) Int. Cl. H01L 21/44

(52) U.S. Cl. 438/687; 257/E21.476

(57) ABSTRACT

A method of making an interconnect structure includes providing a die (120) having an electrically conducting pad (140) and further includes using electrophoresis to place a plurality of nanostructures (150) on the electrically conducting pad.

### FIELD OF THE INVENTION

The disclosed embodiments of the invention relate generally to interconnect structures in semiconductor applications and relate more particularly to methods for making interconnect structures.

### BACKGROUND OF THE INVENTION

Semiconductor dies used in microelectronics applications often are contained in a package in which the die is physically and electrically connected to a substrate with a solder interconnect. However, solder interconnects inherently have low resistance to electromigration, primarily due to their relatively high electrical resistivity and relatively low strength (or modulus). This can be readily understood by calculating the critical product of electromigration (jΔx)_{cr}, as set forth in Equation 1 below,

$${( j Δ x )}_{cr} = \frac{{ΩΔσ}_{th}}{{eZ}^{*} ρ} \qquad ( Equation 1 )$$

where, for a given metal in the solder, e is the fundamental charge, Z* is the effective valence number of the metal atom, ρ is the resistivity of the metal, Ω is the atomic volume of the metal, and Δσₜₕ is the maximum difference between the grain boundary normal stresses at the anode and the cathode end of the segment that the metal can sustain at a given temperature.

A typical solder has a critical product of electromigration approximately 100 times lower than copper (which is used in metallization in a silicon die). For copper, the critical current density beyond which electromigration becomes a problem is approximately 10⁶ Amperes per square centimeter (A/cm²). Therefore, the critical current density beyond which electromigration becomes a problem for solder is approximately 10⁴ A/cm². In other words, solder will face a serious electromigration risk when semiconductor technology reaches a point where current densities reach approximately 10⁴ A/cm², a level that is expected to be reached in the near future. Alternative interconnect structures using carbon nanotubes and the like have been proposed as a solution to the electromigration problem in solder. However, existing techniques such as chemical vapor deposition (CVD) for making such alternative interconnect structures are complex, require temperatures in excess of 500 degrees Celsius (° C.), and can be difficult to implement. Accordingly, there exists a need for a simple, low-temperature method of making an interconnect structure that is better able than solder to resist electromigration.

### BRIEF DESCRIPTION OF THE DRAWINGS

The disclosed embodiments will be better understood from a reading of the following detailed description, taken in conjunction with the accompanying figures in the drawings in which:

FIG. 1 is a cross-sectional view of an interconnect structure that may be made according to an embodiment of the invention;

FIG. 2 is a flowchart illustrating a method of making an interconnect structure according to an embodiment of the invention;

FIG. 3 is a flowchart illustrating another method of making an interconnect structure according to an embodiment of the invention;

FIG. 4 is a cross-sectional view of the interconnect structure of FIG. 1 at a particular point in its manufacturing process according to an embodiment of the invention;

FIG. 5 is a cross-sectional view of the interconnect structure of FIG. 1 at a different point in its manufacturing process according to an embodiment of the invention;

FIG. 6 is a cross-sectional view of the interconnect structure of FIG. 1 at a different point in its manufacturing process according to an embodiment of the invention; and

FIG. 7 is a graph plotting resistance against time for an interconnect structure according to an embodiment of the invention.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

### DETAILED DESCRIPTION OF THE DRAWINGS

In one embodiment of the invention, a method of making an interconnect structure comprises providing a die having an electrically conducting pad and using electrophoresis to place a plurality of nanostructures on the electrically conducting pad. The nanostructures provide a current path of very low electrical resistivity, very high current carrying capability without electromigration damage, and very high thermal conductivity. The interconnect structure greatly enhances electromigration resistance by directing electron flow through nanostructures (in at least one embodiment, through vertically-aligned carbon nanotubes) instead of through relatively weak solder.

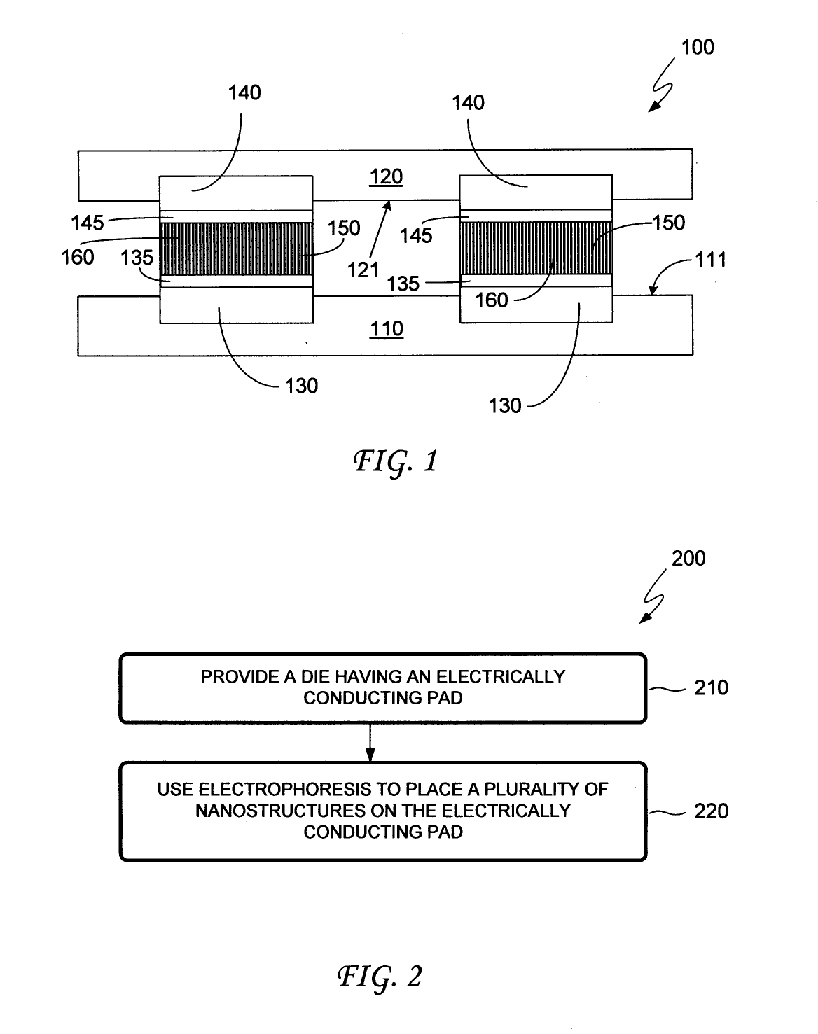

Referring now to the figures, FIG. 1 is a cross-sectional view of an interconnect structure 100 that may be made according to an embodiment of the invention. As illustrated in FIG. 1, interconnect structure 100 comprises a substrate 110 and a die 120. Substrate 110 has a surface 111. Electrically conducting pads 130 are formed on substrate 110, and electrically conducting pads 140 are formed on die 120. Nanostructures 150 lie between pairs of electrically conducting pads 130 and 140. A solder matrix 160 at least partially surrounds nanostructures 150, filling the spaces between nanostructures 150 and forming a solder joint between die 120 and substrate 110.

As an example, die 120 can be a silicon die or the like. As another example, electrically conducting pads 130 and 140 can be formed of copper or the like. As yet another example, nanostructures 150 can be carbon nanotubes (including single-walled and multi-walled carbon nanotubes), inorganic nanotubes, solid nanowires, or the like. Nanostructures 150 have electrical resistivity several times lower than that of even the best metallic conductors such as copper and silver. As example, solder matrix 160 can comprise tin and silver (Sn—Ag) tin, silver, and copper (Sn—Ag—Cu), or the like.

In one embodiment, electrically conducting pad 130 has a low contact resistance metal 135 formed thereon as a surface finish. As an example, low contact resistance metal 135 can comprise nickel, palladium, copper, or the like. Low contact resistance metal 135 tends to reduce contact resistance between nanostructures 150 and electrically conducting pad 130, thus enabling free electron flow across the interface between the nanostructure and the electrically conducting pad. In the same or another embodiment, electrically conducting pad 140 has a low contact resistance metal 145 formed thereon as a surface finish. As an example, low contact resistance metal 145 can be similar to and can serve the same purposes as low contact resistance metal 135. In various embodiments, either one of, both of, or neither of electrically conducting pads 130 and 140 can have a low contact resistance metal formed thereon.

FIG. 2 is a flowchart illustrating a method 200 of making an interconnect structure according to an embodiment of the invention. A step 210 of method 200 is to provide a die having an electrically conducting pad. As an example, the die can be similar to die 120 that is shown in FIG. 1.

A step 220 of method 200 is to use electrophoresis to place a plurality of nanostructures on the electrically conducting pad. Advantageously, electrophoresis may be performed at relatively low temperatures (less than approximately 200° C.) that are compatible with existing assembly processes, thus avoiding much of the complexity and other problems associated with existing manufacturing techniques.

As an example, the nanostructures can be similar to nanostructures 150 that were shown in FIG. 1. In one embodiment, for example, the nanostructures are multi-walled carbon nanotubes. In the same or another embodiment, step 220 comprises at least partially filling a container with a solution comprising carbon nanotubes suspended in a liquid, imparting a first desired surface charge to the carbon nanotubes, imparting a second desired surface charge to the electrically conducting pad, placing an anode in the solution and electrically connecting the anode to a source of direct current, and placing the die in the solution to act as a cathode, and electrically connecting the die to the source of direct current. In a particular embodiment, step 220 comprises causing the plurality of nanostructures to be arranged substantially perpendicularly to a surface of the electrically conducting pad.

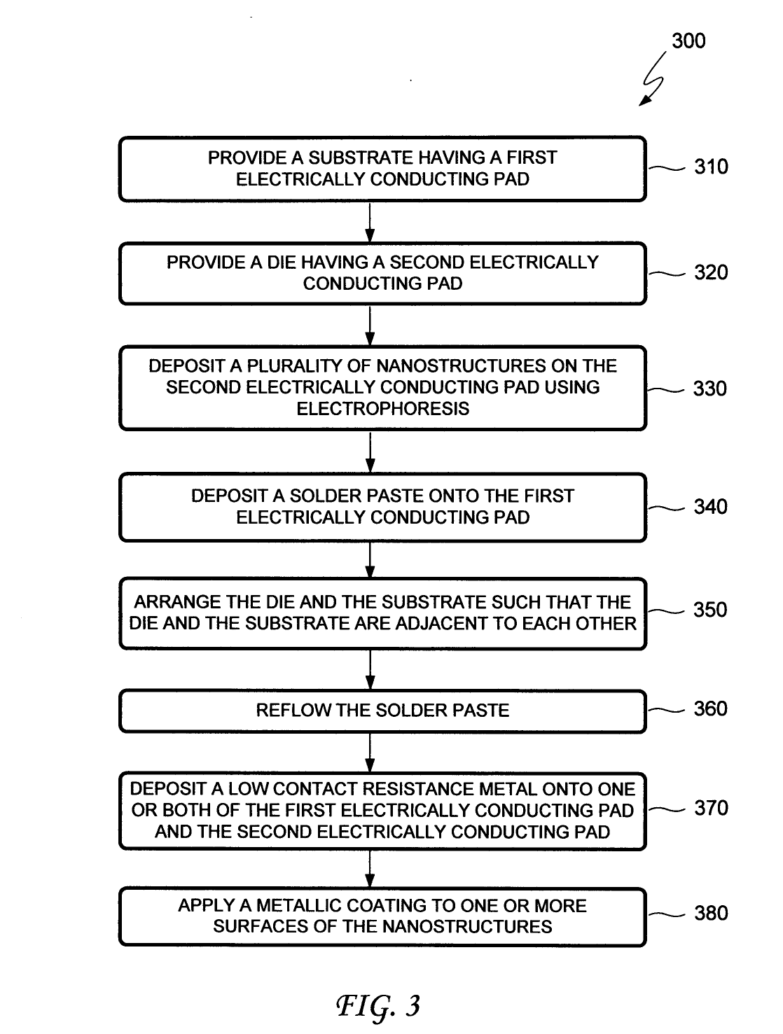

FIG. 3 is a flowchart illustrating a method 300 of making an interconnect structure according to an embodiment of the invention. A step 310 of method 300 is to provide a substrate having a first electrically conducting pad. As an example, the substrate can be similar to substrate 110 that is shown in FIG. 1 and the first electrically conducting pad can be similar to one of electrically conducting pads 130 that were also shown in FIG. 1. In one embodiment, for example, the first electrically conducting pad is a first copper pad. In the same or another embodiment, the first electrically conducting pad is one of a first plurality of copper pads at a surface of the substrate, which surface can be similar to surface 111 of substrate 110 shown in FIG. 1.

A step 320 of method 300 is to provide a die having a second electrically conducting pad. As an example, the die can be similar to die 120 that is shown in FIG. 1 and the second electrically conducting pad can be similar to one of electrically conducting pads 140 that are also shown in FIG. 1. In one embodiment, for example, the second electrically conducting pad is a second copper pad. In the same or another embodiment, the second electrically conducting pad is one of a second plurality of copper pads at a surface of the die, which surface can be similar to surface 121 of die 120 shown in FIG. 1.

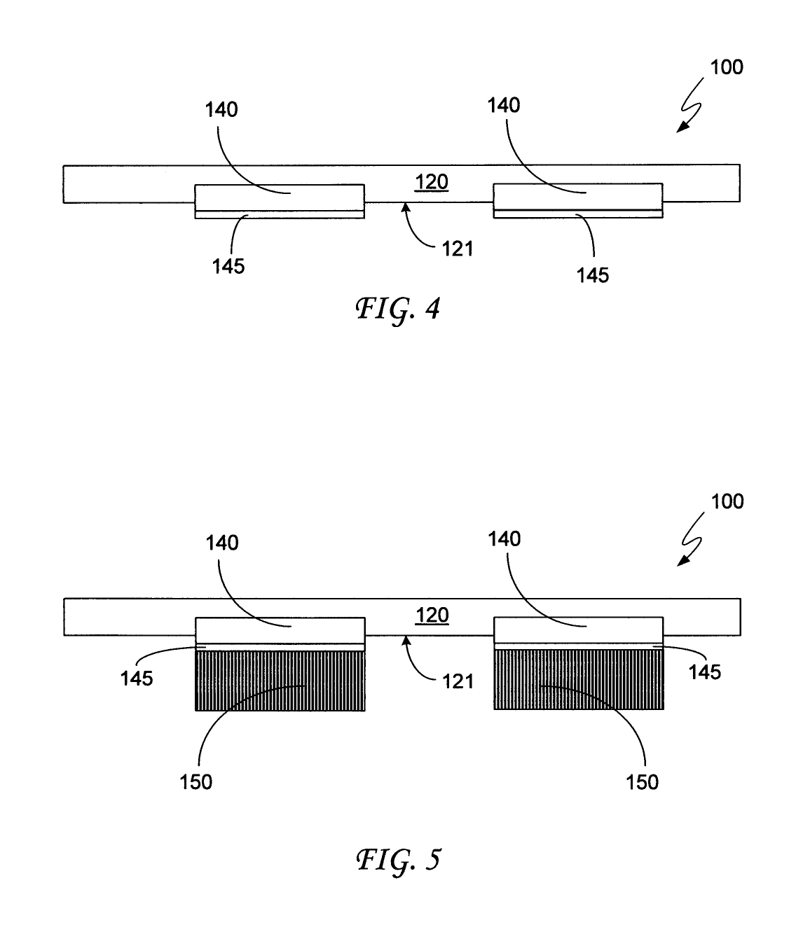

FIG. 4 is a cross-sectional view of interconnect structure 100 at a point in its manufacturing process following the performance of step 320 according to an embodiment of the invention. FIG. 4 depicts electrically conducting pads 140 at surface 121 of die 120 and low contact resistance metal 145 on electrically conducting pads 140.

A step 330 of method 300 is to deposit a plurality of nanostructures on the second electrically conducting pad (or on the second plurality of copper pads) using electrophoresis. As an example, the nanostructures can be similar to nanostructures 150 that were shown in FIG. 1.

FIG. 5 is a cross-sectional view of interconnect structure 100 at a point in its manufacturing process following the performance of step 330 according to an embodiment of the invention. In addition to the features depicted in FIG. 4, FIG. 5 depicts nanostructures 150 at electrically conducting pads 140.

In one embodiment, step 330 comprises at least partially filling a container with a solution comprising carbon nanotubes suspended in a liquid, imparting a first desired surface charge to the carbon nanotubes, imparting a second desired surface charge to the second electrically conducting pad, placing an anode in the solution and electrically connecting the anode to a source of direct current, and placing the die in the solution to act as a cathode, and electrically connecting the die to the source of direct current. In the same or another embodiment, step 330 further comprises causing the plurality of nanostructures to be arranged substantially perpendicularly to a surface of the second electrically conducting pad (or surfaces of the second plurality of copper pads).

As an example, a positive electrical surface charge may be imparted to the carbon nanotubes while a negative electrical surface charge may be imparted to the second electrically conducting pad. The opposing polarity causes carbon nanotubes to be drawn out of the solution and toward the second electrically conducting pad. In one embodiment, imparting a positive electrical surface charge to the carbon nanotubes comprises adding magnesium hexahydrate [Mg(NO3)₂6H₂O] to the solution.

In one embodiment, imparting the first desired surface charge to the carbon nanotubes comprises adding an appropriate chemical to the solution. In the same or another embodiment, method 300 further comprises preventing the carbon nanotubes from settling out of the solution, as for example by agitating the solution with a magnetic agitator or the like.

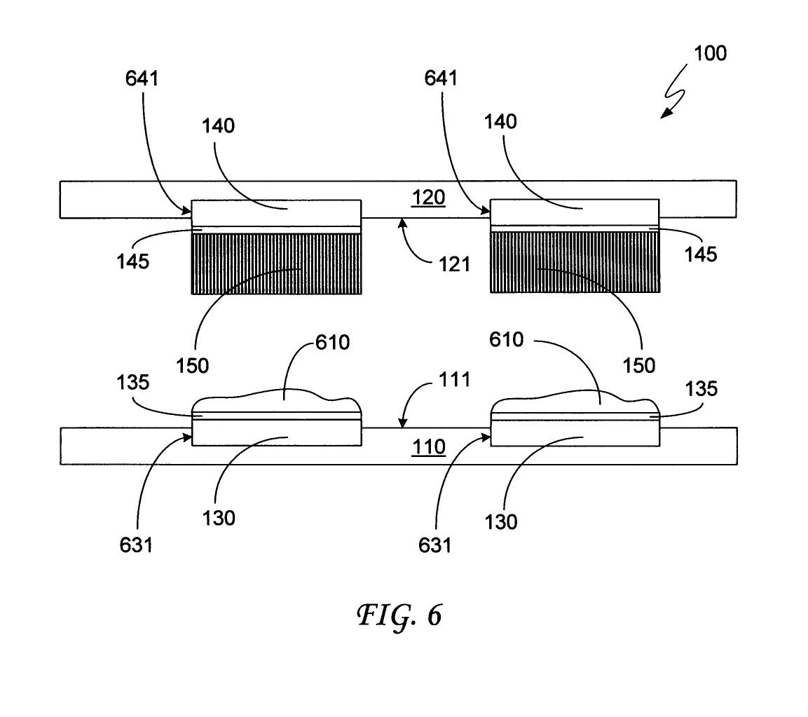

A step 340 of method 300 is to deposit a solder paste onto the first electrically conducting pad (or the first plurality of copper pads). As an example, the solder paste can be similar to a solder paste 610 shown in FIG. 6, which is a cross-sectional view of interconnect structure 100 at a point in its manufacturing process following the performance of step 340 according to an embodiment of the invention. FIG. 6 depicts solder paste 610 on low contact resistance metal 135, which in turn has been deposited on electrically conducting pads 130. In one embodiment, the solder paste is deposited using a stencil printing procedure.

A step 350 of method 300 is to arrange the die and the substrate such that the die and the substrate are adjacent to each other. In one embodiment, step 350 comprises placing the die adjacent to the substrate such that each one of the first plurality of copper pads is aligned with one of the second plurality of copper pads and such that the solder paste and the nanostructures are adjacent to each other. As an example, following step 350 the die and the substrate can be arranged in a manner similar to the arrangement shown in FIG. 6, where die 120 has been positioned adjacent to substrate 110 in such a way that an edge 631 of electrically conducting pad 130 is aligned with an edge 641 of electrically conducting pad 140. In one embodiment, the die is thus positioned using a pick and place procedure.

A step 360 of method 300 is to reflow the solder paste. In one embodiment, step 360 causes the solder paste to go between the nanotubes via capillary action, thus forming a solder matrix that may be similar to solder matrix 160 that is shown in FIG. 1. As an example, step 360 can be performed for bonding purposes, i.e., so that the solder paste is able to strengthen the bond between the nanostructure and the electrically conducting pad, which otherwise may be relatively weak and flimsy. During the reflow, the solder paste melts and flows between the nanostructures due to capillary force, thus forming an inter-metallic compound (IMC) with the electrically conducting pads. After the reflow, an interconnect structure such as interconnect structure 100 as shown in FIG. 1 is realized.

A step 370 of method 300 is to deposit a low contact resistance metal onto one or both of the first electrically conducting pad and the second electrically conducting pad. As an example, the low contact resistance metal may be deposited using an electroplating procedure. In one embodiment, step 370 may be performed immediately following the performance of steps 310 and 320. In another embodiment, the low contact resistance metal may be formed as part of steps 310 and/or 320. In another embodiment, the step or portion of a step that forms the low contact resistance metal may be omitted such that the low contact resistance metal is not formed.

A step 380 of method 300 is to apply a metallic coating to one or more surfaces of the nanostructures. Solders are known to wet on bare surfaces of carbon nanotubes; however, a metallic coating (not shown) may optionally be applied in order to enhance wetting for the solder paste. In one embodiment, step 380 may be performed immediately following step 330. As an example, the metallic coating may be applied using a process such as electroplating, physical vapor deposition, or the like.

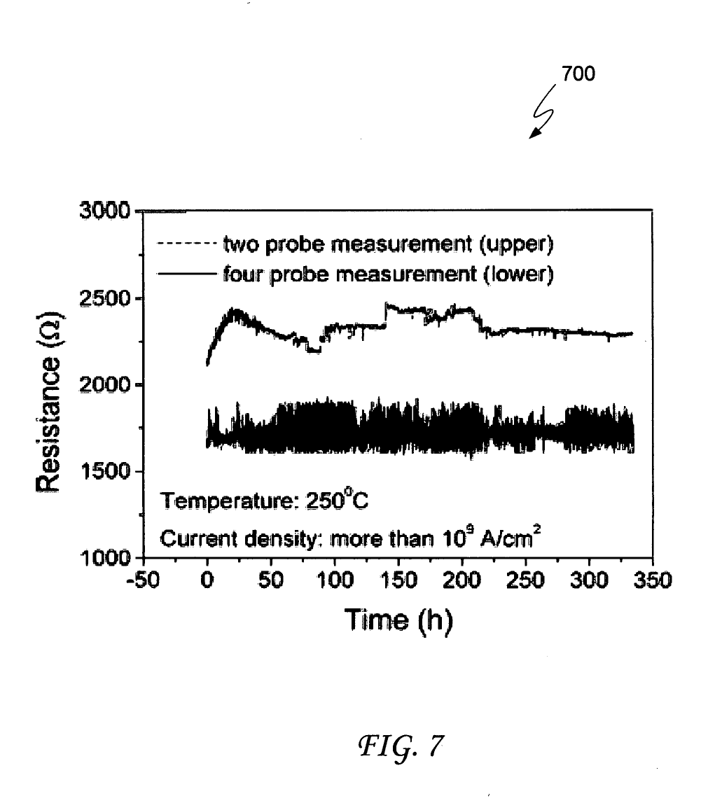

The extraordinary current carrying capability of carbon nanotubes (due at least in part to their strong covalent bonding) is shown in FIG. 7, which is a graph 700 plotting resistance against time for an interconnect structure according to an embodiment of the invention. Graph 700 includes two-probe and four-probe measurements, as shown, both of which show remarkably stable resistance values at a current density greater than 10⁹ A/cm² and a temperature of approximately 250° C. for more than 300 hours. Metallic materials such as copper and the like cannot survive this high current density because of the severe electromigration damage they experience at such current density levels. Furthermore, carbon nanotubes exhibit extraordinarily high thermal conductivity of approximately 3000 Watts per meter per degree Kelvin (W/m−K) along their long axis. This thermal conductivity level far exceeds that of even the best metallic materials such as copper (approximately 420 W/m−K) or even diamond (approximately 2000 W/m−K).

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the methods of making an interconnect structure discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A method of making an interconnect structure, the method comprising:
providing a die having an electrically conducting pad; and
using electrophoresis to place a plurality of nanostructures on the electrically conducting pad.

2. The method of claim 1 wherein:
the nanostructures are multi-walled carbon nanotubes.

3. The method of claim 1 wherein:
placing the plurality of nanostructures comprises:
at least partially filling a container with a solution comprising carbon nanotubes suspended in a liquid;
imparting a first desired surface charge to the plurality of nanostructures;
imparting a second desired surface charge to the electrically conducting pad;
placing an anode in the solution and electrically connecting the anode to a source of direct current; and
placing the die in the solution to act as a cathode, and electrically connecting the die to the source of direct current.

4. The method of claim 3 wherein:
placing the plurality of nanostructures further comprises causing the plurality of nanostructures to be arranged substantially perpendicularly to a surface of the electrically conducting pad.

5. A method of making an interconnect structure, the method comprising:
providing a substrate having a first electrically conducting pad;
providing a die having a second electrically conducting pad;
depositing a plurality of nanostructures on the second electrically conducting pad using electrophoresis;
depositing a solder paste onto the first electrically conducting pad;
arranging the die and the substrate such that the die and the substrate are adjacent to each other; and
reflowing the solder paste.

6. The method of claim 5 wherein:
the first electrically conducting pad comprises a first copper pad; and
the second electrically conducting pad comprises a second copper pad.

7. The method of claim 5 wherein:
the nanostructures are carbon nanotubes.

8. The method of claim 7 wherein:
the carbon nanotubes are multi-walled carbon nanotubes.

9. The method of claim 5 wherein:
the nanostructures are solid nanowires.

10. The method of claim 5 wherein:
depositing the plurality of nanostructures comprises:
at least partially filling a container with a solution comprising carbon nanotubes suspended in a liquid;
imparting a first desired surface charge to the carbon nanotubes;
imparting a second desired surface charge to the second electrically conducting pad;
placing an anode in the solution and electrically connecting the anode to a source of direct current; and
placing the die in the solution to act as a cathode, and electrically connecting the die to the source of direct current.

11. The method of claim 10 wherein:
imparting the first desired surface charge to the carbon nanotubes comprises adding an appropriate chemical to the solution.

12. The method of claim 10 further comprising:
preventing the carbon nanotubes from settling out of the solution.

13. The method of claim 10 wherein:
depositing the plurality of nanostructures further comprises causing the plurality of nanostructures to be arranged substantially perpendicularly to a surface of the second electrically conducting pad.

14. The method of claim 5 further comprising:
depositing a low contact resistance metal onto one or both of the first electrically conducting pad and the second electrically conducting pad.

15. The method of claim 5 further comprising:
applying a metallic coating to one or more surfaces of the nanostructures.

16. A method of making an interconnect structure, the method comprising:
providing a substrate having a first plurality of copper pads at a first surface thereof;
providing a die having a second plurality of copper pads at a second surface thereof;
depositing a low contact resistance metal onto the first copper pad and onto the second copper pad;
depositing a plurality of nanostructures on the second plurality of copper pads using an electrophoresis procedure;
applying a metallic coating to one or more surfaces of the nanostructures;
depositing a solder paste onto the first plurality of copper pads;
placing the die adjacent to the substrate such that each one of the first plurality of copper pads is aligned with one of the second plurality of copper pads and such that the solder paste and the nanostructures are adjacent to each other; and
reflowing the solder paste.

17. The method of claim 16 wherein:
depositing the plurality of nanostructures comprises:
at least partially filling a container with a solution comprising carbon nanotubes suspended in a liquid;
imparting a positive electrical surface charge to the carbon nanotubes;
imparting a negative electrical surface charge to the second copper pad;
placing an anode in the solution and electrically connecting the anode to a source of direct current; and
placing the die in the solution to act as a cathode, and electrically connecting the die to the source of direct current.

18. The method of claim 17 wherein:
imparting the positive electrical surface charge to the carbon nanotubes comprises adding magnesium hexahydrate to the solution.

19. The method of claim 18 further comprising:
agitating the solution to prevent the carbon nanotubes from settling out of the solution.

20. The method of claim 19 wherein:
each one of the second copper pads has a surface that protrudes from the second surface of the die; and
depositing the plurality of nanostructures further comprises causing the plurality of nanostructures to be arranged substantially perpendicularly to the surface of the second copper pad.
